(19) United States
(12) Patent Application Publication
(10) Pub. No.: US 2010/0058141 A1
(43) Pub. Date: Mar. 4, 2010

(54) STORAGE DEVICE AND CONTROL DEVICE

(75) Inventor: Junichi Fukase, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/506,005

(22) Filed: Jul. 20, 2009

(30) Foreign Application Priority Data
Sep. 1, 2008 (JP) 2008-224117

(51) Int. Cl. H03M 13/05; G06F 11/10

(52) U.S. Cl. 714/752; 714/799; 714/E11.032

(57) ABSTRACT

A storage device stores identification information for identifying a pseudo-uncorrectable error sector, which is treated in a pseudo manner as a sector including an uncorrectable error, in the pseudo-uncorrectable error sector. The storage device further performs data processing on the sector by using the identification information stored in the sector. Moreover, the storage device stores log process information indicating whether an error log is registered in the pseudo-uncorrectable error sector in an error process related to the uncorrectable error that is treated to be included in a pseudo manner in the pseudo-uncorrectable error sector. In addition, the storage device performs data processing by using the log process information and the identification information.

### CROSS-REFERENCE TO RELATED APPLICATION

This application is based upon and claims the benefit of priority of the prior Japanese Patent Application No. 2008-224117, filed on Sep. 1, 2008, the entire contents of which are incorporated herein by reference.

### FIELD

The embodiments discussed herein are directed to a storage device, a control device, and a control program.

### BACKGROUND

There has been known a technique for creating an uncorrectable error, which cannot be corrected by using ECC (Error Correction Code) information, on a storage medium such as a magnetic disk. For example, when an uncorrectable error is included in a sector present in an old magnetic disk to be repaired, a repair is performed by copying data present in the old magnetic disk to be repaired to a new magnetic disk as it is. In this case, the technique intentionally creates an uncorrectable error in the sector of the new magnetic disk corresponding to the sector of the old magnetic disk that has an uncorrectable error.

Moreover, there has been conventionally known a technique for creating an uncorrectable error in a pseudo manner without actually creating an uncorrectable error in a sector. Specifically, a magnetic disk includes a memory separated from a storage medium and stores in the memory identification information indicating that the sector has an uncorrectable error. Then, a control device for controlling the storage medium refers to the memory and treats in a pseudo manner the sector specified by the identification information stored in the memory as a sector having an uncorrectable error. In addition, a technique for storing copyright managing information in ECC included in a sector has been known as disclosed in, for example, Japanese Laid-open Patent Publication No. 2001-110136.

However, the conventional technology has a problem that identification information cannot be stored appropriately. In other words, for example, when realizing the conventional technology as described above, a memory having a capacity for storing all identification information must be provided separately from a storage medium.

### SUMMARY

According to an aspect of the invention, a storage device includes a storage control unit that stores identification information for identifying a pseudo-uncorrectable error sector in the pseudo-uncorrectable error sector, the pseudo-uncorrectable error sector being treated in a pseudo manner as a sector including an uncorrectable error; and a data processing control unit that performs data processing on the sector by using the identification information stored in the sector by the storage control unit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a schematic diagram for explaining a storage device according to a first embodiment;

FIG. 2 is a block diagram for explaining a configuration of the storage device according to the first embodiment;

FIG. 3 is a diagram for explaining an example of a sector format;

FIG. 4 is a diagram for explaining an example of an area of the sector format in which management information is input;

FIG. 5 is a diagram for explaining an example of management information used in the first embodiment;

FIG. 6A is a diagram for explaining a formatter unit according to the first embodiment;

FIG. 6B is a diagram for explaining a formatter unit according to the first embodiment;

FIG. 7 is a table for explaining operation modes according to the first embodiment;

FIG. 8 is a flowchart for explaining a flow of a write command issuing process performed by a host in the first embodiment;

FIG. 9 is a flowchart for explaining a flow of a read command issuing process performed by the host in the first embodiment;

FIG. 10 is a flowchart for explaining a flow of a normal writing process performed by the storage device according to the first embodiment;

FIG. 11 is a flowchart for explaining a flow of a writing process for creating an uncorrectable error performed by the storage device according to the first embodiment;

FIG. 12 is a flowchart for explaining a flow of a reading process performed by the storage device according to the first embodiment;

FIG. 13 is a flowchart for explaining a flow of a command reception process in an idle state performed by a drive in the first embodiment;

FIG. 14 is a flowchart for explaining a flow of a command interrupt process performed by the drive in the first embodiment;

FIG. 15 is a flowchart for explaining a flow of a command execution process performed by the drive in the first embodiment; and

FIG. 16 is a diagram for explaining a computer having the same function as that of the storage device according to the first embodiment.

### DESCRIPTION OF EMBODIMENTS

Preferred embodiments of the present invention will be explained with reference to accompanying drawings. Explained below are a brief description of a storage device, a configuration of the storage device, an operation mode, and a process flow of the storage device according to a first embodiment. After that, other embodiments will be explained.

### [a] First Embodiment

Brief Description of Storage Device

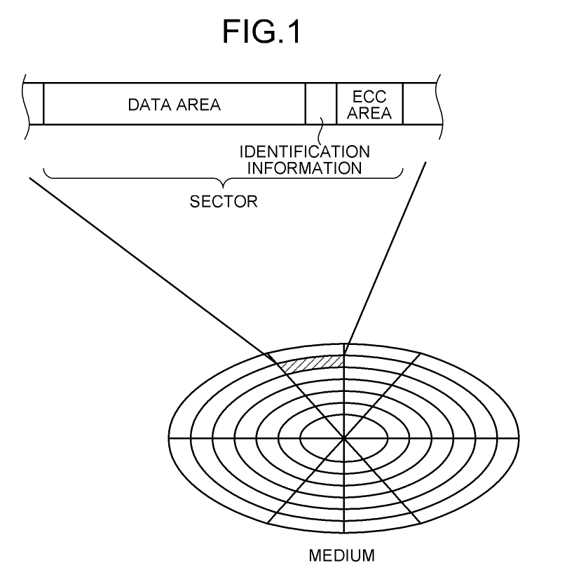

First, a brief description of a storage device according to the first embodiment will be explained with reference to FIG. 1. FIG. 1 is a schematic diagram for explaining the storage device according to the first embodiment.

The storage device according to the first embodiment stores identification information for identifying a pseudo-uncorrectable error sector, which is treated in a pseudo manner as a sector including an uncorrectable error, in the pseudo-uncorrectable error sector. In other words, as illustrated in FIG. 1, the storage device stores identification information for a sector in an area that is present in the sector provided on a storage medium included in the storage device.

The storage device according to the first embodiment performs data processing on a sector by using the identification information stored in the sector. For example, when the storage device reads identification information indicating that a sector is a pseudo-uncorrectable error sector, the storage device performs data processing on the sector having the identification information so that the sector acts as a sector including an uncorrectable error.

Because of this, the storage device according to the first embodiment can appropriately store identification information. For example, the storage device can store identification information for all sectors even when identification information for all sectors is stored, unlike with the technique for storing identification information in a memory for identification information.

Configuration of Storage Device

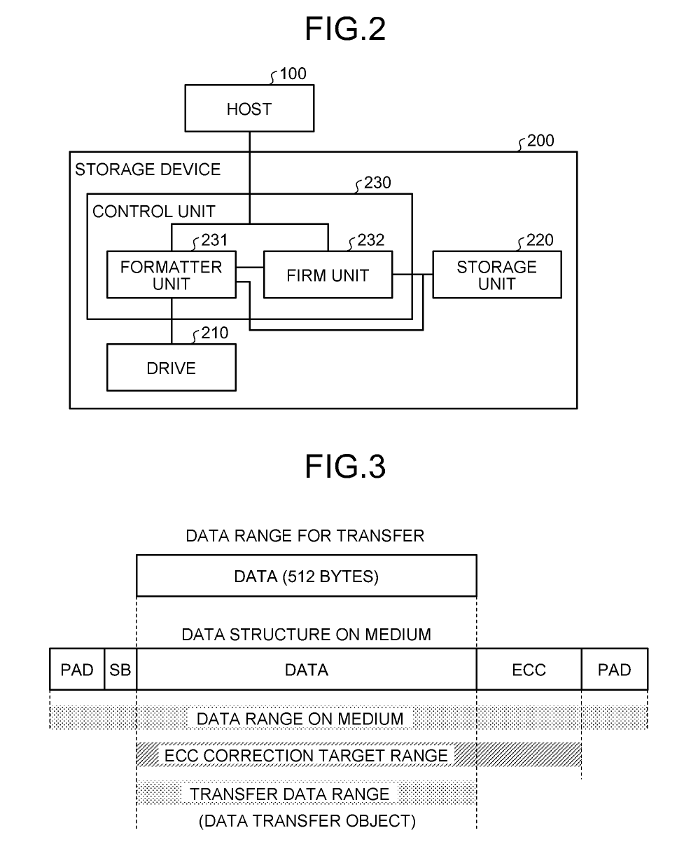

Next, a configuration of a storage device 200 illustrated in FIG. 1 will be explained with reference to FIG. 2. FIG. 2 is a block diagram for explaining a configuration of the storage device 200 according to the first embodiment. As illustrated in FIG. 2, the storage device 200 is connected to a host 100 and includes a drive 210, a storage unit 220, and a control unit 230.

Hereinafter, a process related to a pseudo-uncorrectable error sector will be explained in detail and other processes will be briefly explained. In addition, for convenience of explanation, an uncorrectable error treated to be included in a pseudo-uncorrectable error sector is referred to as “a pseudo-uncorrectable error”.

The host 100 is a computer or the like that is connected to the storage device 200 and transmits and receives information to and from the storage device 200. For example, the host 100 issues a write command that is a request for writing information into the drive 210 and a read command that is a request for reading information from the drive 210 and sends the commands to the storage device 200, in response to the request from a user. Moreover, the host 100 receives information from the storage device 200 and outputs the information to the user.

The storage device 200 is explained again. The drive 210 is connected to the control unit 230 and includes a storage medium. Moreover, the drive 210 stores therein information specified by a write command sent from the host 100. The drive 210 receives a command from the control unit 230 and performs a process based on the received command. Specifically, the drive 210 includes a memory (not illustrated in FIG. 2) for storing therein received commands and stores the commands received from the control unit 230 in the memory as a command sequence. Then, the drive 210 executes the commands included in the command sequence. The details of the process performed by the drive 210 will be below explained.

The drive 210 stores information in each sector provided in the storage medium. For example, the drive 210 uses a general sector format as illustrated in FIG. 3. FIG. 3 is a diagram for explaining an example of a sector format. In the general sector format illustrated in FIG. 3, “PAD” is a buffer area that absorbs a delay time caused by the reproduction of data and “SB” is an area that stores information indicating the start position of a data area. “DATA” is an area into which information specified by a write command sent from the host 100 is inputted.

Moreover, “ECC” is an area that stores ECC information used for correcting an error included in information when reading the information from a sector. In the general sector format illustrated in FIG. 3, areas to be corrected by “ECC” are “DATA” and “ECC”. Moreover, an area that stores information specified by a write command and a read command is “DATA”. An uncorrectable error is an error that cannot be corrected by ECC information.

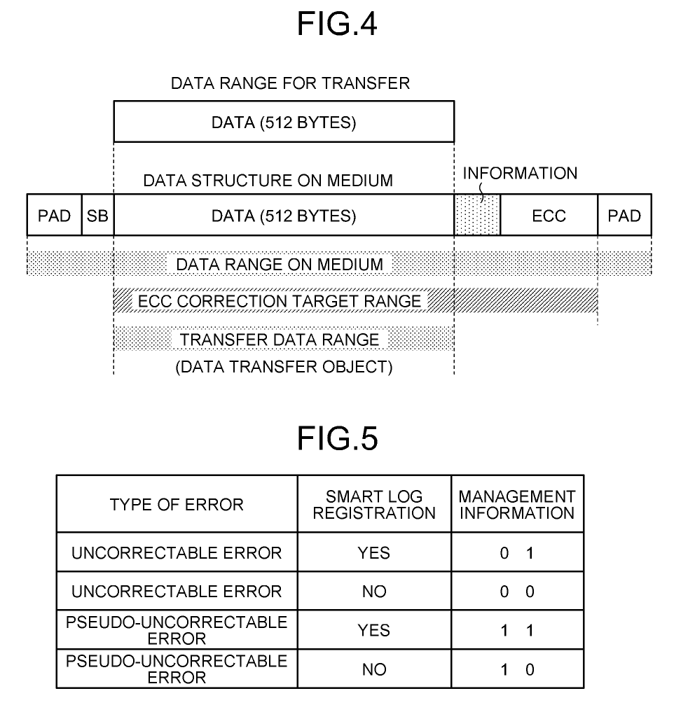

The drive 210 stores identification information, which identifies a pseudo-uncorrectable error sector treated in a pseudo manner as a sector including an uncorrectable error, in the pseudo-uncorrectable error sector. In an example illustrated in FIG. 4, the drive 210 provides an “information” area only used for inputting identification information between “DATA” and “ECC” and stores the identification information in the “information” area. In addition, in the sector format illustrated in FIG. 4, areas to be corrected by “ECC” are “DATA”, “information”, and “ECC”. FIG. 4 is a diagram for explaining an example of an area of the sector format in which management information is input.

Moreover, the drive 210 stores log process information indicating whether a Self-Monitoring Analysis and Reporting Technology (SMART) log is registered in a pseudo-uncorrectable error sector in an error process related to an uncorrectable error treated to be included in a pseudo manner in the pseudo-uncorrectable error sector. For example, as illustrated in “information” of FIG. 4, the drive 210 stores the log process information in an area between “DATA” and “ECC”. The SMART log is, for example, information issued by the storage device 200 with respect to the present condition of the storage medium. For example, the information is the number of bad sectors, the occurrence frequency of errors, or the like.

In regard to the first embodiment, it will be explained about when identification information and log process information are together treated as management information. In other words, management information indicates whether a type of error to be created is an uncorrectable error or a pseudo-uncorrectable error and also indicates whether a SMART log related to the sector is registered or not.

Hereinafter, as illustrated in FIG. 5, it will be explained about when binary data is used as the management information. FIG. 5 is a diagram for explaining an example of management information used in the first embodiment. In regard to a bit indicating the type of error, the bit is “0” when a sector is not treated as a pseudo-uncorrectable error sector, in other words, when the sector is treated as a sector including an uncorrectable error and the uncorrectable error is actually created. On the other hand, in regard to a bit indicating the type of error, the bit is “1” when an error is treated as a pseudo-uncorrectable error, in other words, when a sector is treated as a pseudo-uncorrectable error sector. Moreover, in regard to a bit indicating log process information, the bit is “1” when a SMART log is registered; the bit is “0” when the SMART log is not registered. In other words, the management information is “11” when a sector is a pseudo-uncorrectable error sector and a SMART log is registered.

In addition, information stored in the drive 210 is input by the control unit 230 and is used by the control unit 230. In other words, as described below, information is written by the control unit 230 based on a write command output from the host 100 and is also read by the control unit 230 based on a read command output from the host 100.

The storage unit 220 is connected to the control unit 230 and stores therein data to be used for a control process performed by the control unit 230. For example, the storage unit 220 stores a SMART log for the drive 210 and configuration information to be used when the control unit 230 reads information from the drive 210 or writes information into the drive 210. The storage unit 220 is, for example, a ROM (Read Only Memory) or a flash memory.

In addition, although it is not particularly mentioned below, when performing a writing process or a reading process, each unit within the control unit 230 reads configuration information corresponding to the process from the storage unit 220 and performs a process by using the configuration information. The storage unit 220 previously acquires the configuration information by the user and also acquires the SMART log through the control unit 230.

The control unit 230 includes an internal memory for storing therein a program that prescribes various types of control processing procedures and performs various control processes. Moreover, the control unit 230 is connected to the host 100, the drive 210, and the storage unit 220, and includes a formatter unit 231 and a firm unit 232.

The formatter unit 231 realizes a function that acts as a storage control unit and a log-process-information storage control unit. Moreover, the formatter unit 231 and the firm unit 232 realize a function that acts as a data processing control unit in cooperation with each other.

When it is explained about the formatter unit 231 and the firm unit 232, the descriptions related to inputting a command into the drive 210 are omitted for convenience of explanation.

Formatter Unit

The formatter unit 231 is connected to the host 100, the drive 210, the storage unit 220, and the firm unit 232. Moreover, when the formatter unit 231 accepts a write command and a read command from the host 100, the formatter unit 231 performs a process corresponding to each command on the drive 210 by using the configuration information stored in the storage unit 220. In other words, as explained below, the formatter unit 231 performs the writing process on the drive 210 and also performs the reading process on the drive 210 along with the firm unit 232. Although it is not particularly mentioned below, when the formatter unit 231 performs processes corresponding to the write command and the read command on the drive 210, the formatter unit 231 inputs the commands into a storage unit included in the drive 210 as a command sequence.

Writing Process by Formatter Unit

The formatter unit 231 performs a normal writing process based on the write command accepted from the host 100, performs a writing process for creating an uncorrectable error, and also performs a writing process for creating a pseudo-uncorrectable error.

The writing process for creating an uncorrectable error is a process that creates an uncorrectable error sector actually including an uncorrectable error. Moreover, the writing process for creating a pseudo-uncorrectable error is a writing process that creates a pseudo-uncorrectable error sector.

Normal Writing Process

The normal writing process will be explained. Specifically, an operation mode “0” to be described below corresponds to the normal writing process. The formatter unit 231 accepts a write command for performing the normal writing process from the host 100. Specifically, the formatter unit 231 accepts an instruction for performing the normal writing process and sector information for identifying a sector to be processed, as a write command. In addition, the details of an operation mode will be explained below.

The formatter unit 231 writes information specified by the instruction for performing the normal writing process into a sector identified by the sector information accepted as the write command. In addition, when performing the normal writing process, the formatter unit 231 does not perform a writing process for creating an uncorrectable error and a writing process for creating a pseudo-uncorrectable error.

On the other hand, for example, when an error occurs in the writing process performed on the sector identified by the sector information, the formatter unit 231 executes a predetermined number of retries. Furthermore, when the writing process does not succeed regardless of the execution of the predetermined number of retries, the formatter unit 231 performs an error process. For example, the formatter unit 231 sends information indicating that the writing process has failed to the host 100.

In addition, when performing a retry, the formatter unit 231, for example, computes an address indicating a storage area having an error and registers information indicating that an error has occurred in the storage unit 220. Then, the formatter unit 231 reads configuration information used for performing the retry from the storage unit 220 and again performs the writing process.

Writing Process for Creating Pseudo-Uncorrectable Error

The writing process for creating an uncorrectable error and the writing process for creating a pseudo-uncorrectable error will be explained. Specifically, operation modes “1” to “3” to be described below correspond to the processes. The formatter unit 231 accepts write commands corresponding to the operation modes “1” to “3”.

Hereinafter, the operation mode “1” is associated with a write command for creating an uncorrectable error and the operation modes “2” and “3” are associated with write commands for creating a pseudo-uncorrectable error.

Specifically, the formatter unit 231 accepts write commands corresponding to the operation modes “1” to “3” as a write command. For example, the formatter unit 231 accepts an instruction for performing the writing process creating an uncorrectable error and sector information for identifying a sector to be written, as a write command corresponding to the operation mode “1”. Moreover, for example, the formatter unit 231 accepts an instruction for performing the writing process creating a pseudo-uncorrectable error in accordance with the operation mode “2” or “3” and sector information for identifying a sector to be written, as a write command corresponding to the operation mode “2” or “3”.

Specifically, when accepting a write command, the formatter unit 231 performs a reading process on a sector identified by the sector information accepted as the write command. In other words, the formatter unit 231 confirms whether a sector for creating an uncorrectable error or a pseudo-uncorrectable error can be actually read, i.e., the sector is breaking down.

For example, when an error occurs in the reading process performed on the sector identified by the sector information, the formatter unit 231 executes a predetermined number of retries. Moreover, when the reading process does not succeed irrespective of the execution of the predetermined number of retries, the formatter unit 231 performs an error process. For example, the formatter unit 231 sends information indicating that the writing process has failed to the host 100.

When the reading process performed on the sector identified by the sector information terminates, the formatter unit 231 reads configuration information corresponding to the write command accepted from the host 100 from the storage unit 220. Then, the formatter unit 231 performs the writing process by using the configuration information.

Specifically, the formatter unit 231 creates an uncorrectable error in the “DATA” area of the sector identified by the sector information when the uncorrectable error is created as the writing process, i.e., when the operation mode to be described below is “1”.

Moreover, when a pseudo-uncorrectable error is created, i.e., when the operation mode is “2” or “3”, the formatter unit 231 inputs management information in an area other than the “DATA” area without changing the “DATA” area of the sector. In other words, the formatter unit 231 inputs management information of which a bit related to the type of error is “1”. Referring to an example illustrated in FIG. 4, the formatter unit 231 inputs the management information into the “information” area. For example, the formatter unit 231 inputs the management information of which a bit related to the type of error is “1”.

For example, when an error occurs in the process for creating an uncorrectable error as a writing process, the formatter unit 231 executes a retry process. In this case, when the writing process does not succeed irrespective of the execution of a predetermined number of retry processes, the formatter unit 231 performs an error process. For example, the formatter unit 231 sends information indicating that the writing process has failed to the host 100.

Reading Process by Formatter Unit

The reading process by the formatter unit 231 will be explained. The formatter unit 231 accepts a read command for performing the reading process from the host 100. Specifically, the formatter unit 231 accepts, as a read command, a read command for performing a normal reading process and a read command for performing a reading process in accordance with the operation mode “4”. In this case, the operation mode “4” is an instruction indicating that the reading process is performed without the use of management information.

For example, the formatter unit 231 accepts an instruction for performing the normal reading process and sector information for identifying a sector to be read, as a read command for performing the normal reading process. Moreover, the formatter unit 231 accepts an instruction for executing a read command in accordance with the operation mode “4” and sector information for identifying a sector to be read, as a read command for performing the reading process in accordance with the operation mode “4”. Then, the formatter unit 231 sends information read from the drive 210 by performing the reading process to the host 100.

When a command is the read command for performing the reading process in accordance with the operation mode “4” the formatter unit 231 performs the reading process on the sector identified by the accepted sector information regardless of the management information stored in the sector to be read. In other words, when a command is the read command for performing the reading process in accordance with the operation mode “4”, the formatter unit 231 does not perform a process in which a sector is treated as a sector including a pseudo-uncorrectable error even if management information indicating that the sector is a pseudo-uncorrectable error sector is stored in the sector.

Referring to the sector format illustrated in FIG. 4, the formatter unit 231 reads an area from “DATA” to “ECC” from the sector to be read. In this case, when an error is not read from the sector to be read, the formatter unit 231 sends the read information to the host 100 and terminates the process on the sector. On the other hand, when an error is read from the sector to be read, the formatter unit 231 stops the process and sends information indicating that an error has been detected to the firm unit 232. After that, when receiving information indicating that an error process has terminated from the firm unit 232, the formatter unit 231 sends the read information to the host 100 and terminates the process on the sector.

Moreover, when a plurality of sectors is identified by the accepted sector information, the formatter unit 231 performs a similar reading process on the next sector. The formatter unit 231 performs the reading process on all the sectors.

When a command is not the read command for performing the reading process in accordance with the operation mode “4”, the formatter unit 231 performs a reading process based on the management information on the sector identified by the accepted sector information. In other words, referring to the sector format illustrated in FIG. 4, the formatter unit 231 reads an area from “DATA” to “ECC” from the sector to be read.

Moreover, when an error is read from the sector to be read, the formatter unit 231 stops the process and sends information indicating that an error has been detected to the firm unit 232. When a bit related to the type of error is “1” indicating a pseudo-uncorrectable error, the formatter unit 231 stops the process on the management information stored in the read “information” and sends the management information to the firm unit 232.

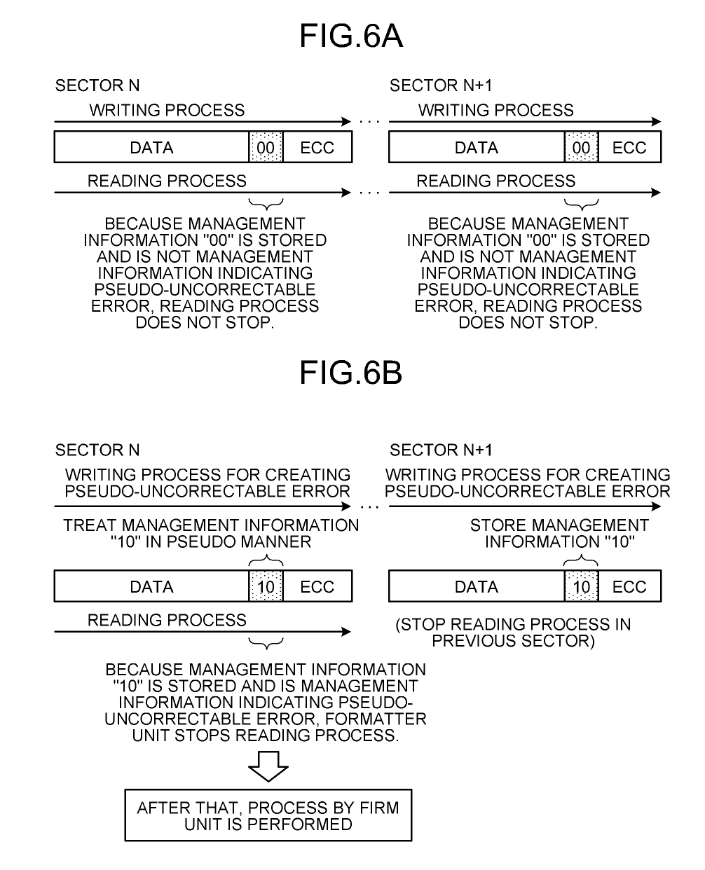

It will be explained with reference to FIGS. 6A and 6B about when a sector “N” and a sector “N+1” are specified by sector information and the formatter unit 231 does not read an error from the sector “N” and the sector “N+1”. In other words, it is assumed that an uncorrectable error is not included in the sector “N” and the sector “N+1”. FIGS. 6A and 6B are diagrams for explaining the formatter unit according to the first embodiment.

As illustrated in FIG. 6A, because management information for the sector “N” is “00” and a bit related to the type of error is not “1” indicating a pseudo-uncorrectable error, the formatter unit 231 performs a reading process on the sector “N+1” without stopping the process.

However, as illustrated in FIG. 6B, because management information for the sector “N” is “10” and a bit related to the type of error is “1” that indicates a pseudo-uncorrectable error, the formatter unit 231 stops the process. Then, after a process by the firm unit 232 is performed as described below, the formatter unit 231 performs the reading process on the sector “N+1”.

Moreover, after sending the information indicating that an error has been detected and the management information to the firm unit 232, the formatter unit 231 terminates the process on the sector when receiving the information indicating that the process has terminated from the firm unit 232. After that, the formatter unit 231 performs the process on all the sectors.

Firm Unit

The firm unit 232 is connected to the host 100, the storage unit 220, and the formatter unit 231, and performs an error process, a SMART log registration process, and an error reporting process to the host when receiving information from the formatter unit 231.

When receiving information indicating that an error has been detected from the formatter unit 231, the firm unit 232 executes a retry process. In this case, when the error is not fixed irrespective of the execution of a predetermined number of retry processes, the firm unit 232 performs an error-post-process. For example, the firm unit 232 sends information indicating that an error has occurred to the host 100 and registers a SMART log in the storage unit 220. On the other hand, when the error is fixed, the firm unit 232 modifies information corresponding to an error within the information read by the formatter unit 231.

Moreover, when receiving management information from the formatter unit 231, the firm unit 232 performs data processing on the sector by using the management information. First, the firm unit 232 confirms the content of the management information. In this case, when the management information is “11”, i.e., when the type of error is a pseudo-uncorrectable error and the SMART log is registered, the firm unit 232 performs a reading process related to the operation mode “2”. The reading process related to the operation mode “2” means that information indicating that the sector has the pseudo-uncorrectable error is sent to the host 100 and the SMART log related to the pseudo-uncorrectable error is registered in the storage unit 220. Then, the firm unit 232 sends information indicating that the process has terminated to the formatter unit 231.

When the management information is “10”, i.e., when the type of error is a pseudo-uncorrectable error and the SMART log is not registered, the firm unit 232 performs a reading process related to the operation mode “3”. The reading process related to the operation mode “3” means that information indicating that the sector has the pseudo-uncorrectable error is sent to the host 100 and the SMART log related to the pseudo-uncorrectable error is not registered in the storage unit 220. Then, the firm unit 232 sends the information indicating that the process has terminated to the formatter unit 231.

Operation Mode and Management Information

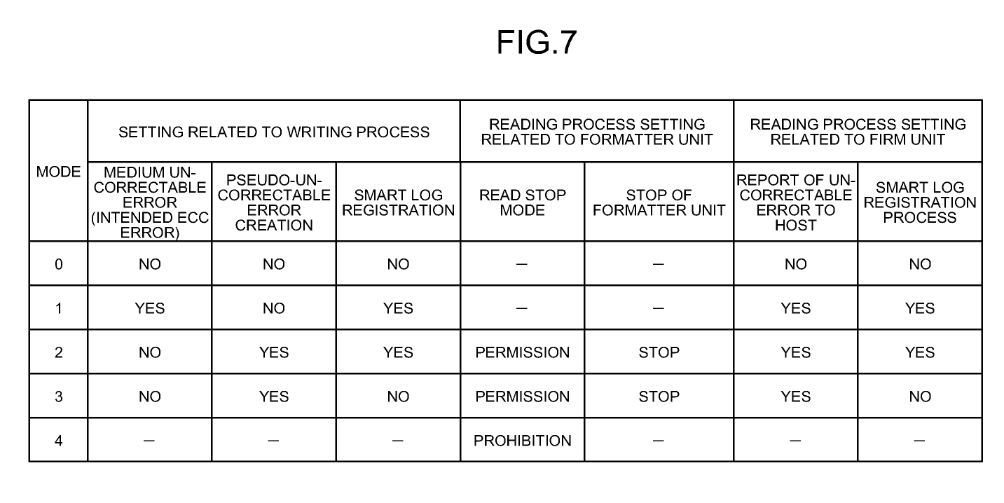

Next, the operation modes according to the first embodiment will be further explained with reference to FIG. 7. FIG. 7 is a table for explaining the operation modes according to the first embodiment. In FIG. 7, setting related to the writing process, setting of the reading process related to the formatter unit 231, and setting of the reading process related to the firm unit 232 are expressed in association with each operation mode.

In the setting related to the writing process, “a medium uncorrectable error (an intended ECC error)” indicates the presence or absence of the creation of an uncorrectable error. Specifically, when a medium uncorrectable error (an intended ECC error) is present (“YES” in the table), the formatter unit 231 creates an uncorrectable error during the writing process. On the other hand, when a medium uncorrectable error (an intended ECC error) is not present, the formatter unit 231 does not create an uncorrectable error during the writing process.

Moreover, in the setting related to the writing process, “the creation of pseudo-uncorrectable error” indicates the presence or absence of the creation of pseudo-uncorrectable error. Specifically, when the creation of pseudo-uncorrectable error is present (“YES” in the table), the formatter unit 231 creates a pseudo-uncorrectable error during the writing process. In other words, the formatter unit 231 writes the bit “1” related to the type of error into the sector as management information. On the other hand, when the creation of pseudo-uncorrectable error is “not present”, the formatter unit 231 does not create a pseudo-uncorrectable error during the writing process.

Moreover, in the setting related to the writing process, “the registration of SMART log” indicates the presence or absence of the registration of SMART log. Specifically, when the registration of SMART log is present (“YES” in the table), the formatter unit 231 writes management information indicating that the SMART log is registered into the sector during the writing process. In other words, the formatter unit 231 writes the bit “1” specifying the presence or absence of the registration of SMART log in the sector as management information. On the other hand, when the registration of SMART log is not present (“NO” in the table), the formatter unit 231 writes management information indicating that the SMART log is not registered into the sector during the writing process. In other words, the formatter unit 231 writes the bit “0” specifying the presence or absence of the registration of SMART log into the sector as management information.

Moreover, in the setting of the reading process related to the formatter unit 231, “a read stop mode” and “the stop of the formatter unit” indicate whether the formatter unit 231 stops the process when the management information indicating a pseudo-uncorrectable error is read. Specifically, in the case of “permission” of the read stop mode and “stop” of the stop of the formatter unit, the formatter unit 231 stops the process. In the case of “prohibition” of the read stop mode, the formatter unit 231 does not stop the process and does not also perform a process corresponding to a pseudo-uncorrectable error. In addition, in the setting of the reading process related to the formatter unit 231, “−” indicates that a mode is an operation mode that does not assume a pseudo-uncorrectable error.

In the setting of the reading process related to the firm unit 232, “the report of uncorrectable error to the host” indicates whether the report is performed on the host 100 when an uncorrectable error or a pseudo-uncorrectable error is read. Specifically, when the report of uncorrectable error to the host is present (“YES” in the table), the firm unit 232 reports the fact to the host 100 during the reading process. On the other hand, when the report of uncorrectable error to the host is not present (“NO” in the table), the firm unit 232 does not report to the host 100 during the reading process.

In the setting of the reading process related to the firm unit 232, “the registration of SMART log” indicates the presence or absence of the registration of SMART log. Specifically, when the registration of SMART log is present (“YES” in the table), the firm unit 232 registers a SMART log during the reading process. On the other hand, when the registration of SMART log is not present (“NO” in the table), the firm unit 232 does not register a SMART log during the reading process.

Operation Mode 0

Because the normal writing process is performed in the operation mode “0”, its description is omitted.

Operation Mode 1

The operation mode “1” is now explained. The operation mode “1” is similar to a function that intentionally creates an uncorrectable error in a Write Long command. In the operation mode “1”, the formatter unit 231 actually creates an uncorrectable error. Moreover, the formatter unit 231 and the firm unit 232 perform a normal retry process and then perform an error process during the reading process regardless of the setting of read stop mode.

A technique for actually creating an uncorrectable error is, for example, to create an uncorrectable error by setting a Seed value different from the ordinary during the writing process and using an ordinary Seed value during the reading process.

In the operation mode “1”, when the reading process is performed on the sector having an uncorrectable error, an error is reported to the host 100 by the formatter unit 231 or the firm unit 232 and a SMART log is accumulated, similarly to a normal uncorrectable error caused by the degradation of the drive. In other words, the attribute information of the drive 210 is deteriorated.

The operation mode “1” is used when the host 100 wants to create an uncorrectable error in an arbitrary sector without changing an operation mode into the operation modes “2” to “4”. The Write Long command is a 28-bit LBA (Logical Block Addressing) command that is already defined to “Obsolete.” on the ATA specification, and is used in combination with a Read Long command. The Write Long command has been originally used to test an ECC error.

Practical Use of Operation Mode 1

The operation mode “1” is used, for example, to repair HDD (Hard Disk Drive). In other words, when an original HDD that is HDD in a PC returned from an end user for repairs has a malfunction, data are generally erased during repairing the original HDD. However, when the original HDD has important data, it is not unusual that a user requests the restoration of data present in an area that does not a malfunction. In this case, sectors of the original HDD that can be normally read can be reproduced into sectors of a new HDD. However, sectors having an uncorrectable error cannot be reproduced. Because a new HDD does not originally have an uncorrectable error, there is a possibility that data different from that of the original HDD are read from the sectors that are not reproduced. When the HDD is connected to the original PC or the like in this state, it seems that “all data have been restored”. However, there is considered a possibility that a secondary malfunction or loss is actually caused due to the change of the content of the file. Therefore, when recovering data of the damaged original HDD, it is general to intentionally make the sector error of the same number in a new HDD and to return the new HDD to the end user. In addition, because the new HDD is not out of order, the new HDD can be restored as a normal drive if the sector is overwritten by “data erasing software” or the like. However, SMART logs are accumulated in accordance with the number of accesses.

Operation Mode 2

The operation mode “2” will be explained. When a write command is issued in the operation mode “2”, the formatter unit 231 once performs the reading process on a sector to be processed. Then, the formatter unit 231 writes management information indicating that “a pseudo-uncorrectable error is present and a SMART log is registered” into the sector to be processed.

In this case, when the reading process using management information is performed on the pseudo-uncorrectable error sector created in accordance with the operation mode “2”, i.e., when an operation mode is not the operation mode “4”, the read stop mode becomes “permission”. As a result, the formatter unit 231 stops the process when performing the reading process. After that, the firm unit 232 performs a SMART log registration process and a report to the host based on the management information read from the formatter unit 231, and thus the SMART log is accumulated. In addition, when the formatter unit 231 is stopped and a stop error other than the pseudo-uncorrectable error is generated, a retry operation is performed.

The sector in which the management information indicating that “the pseudo-uncorrectable error is present” and “the SMART log is registered” is written is treated as a normal sector not having an error by performing the reading process by using the operation mode “4”, and thus the reading process can be performed on the sector.

Practical Use of Operation Mode 2

From the viewpoint of the host 100, the operation mode “2” is the same as the operation mode “1” meaning that “an uncorrectable error is present and a SMART log is registered”. However, in the operation mode “2”, the retry processing time can be reduced because an error is treated as an immediate error by a pseudo-uncorrectable error. In addition, a usual retry processing time is several seconds.

Moreover, when the host 100 verifies an operation caused by the fault of HDD under an environment such as a system (a server) in the operation mode “2”, the reading process may be performed on an error point many times. At this time, a time required for the reading process can be reduced.

Operation Mode 3

The operation mode “3” is substantially similar to the operation mode “2”. However, the difference is that the firm unit 232 does not perform the registration process of the SMART log.

In other words, in the operation mode “3”, when the reading process is performed on the sector created in accordance with the operation mode “3”, the information indicating that a pseudo-uncorrectable error is present is reported to the host 100. However, the SMART log is not newly accumulated. Therefore, attribute information such as the SMART log is not deteriorated. As a result, because the attribute information such as the SMART log is not deteriorated when the sector is a sector in which a pseudo-uncorrectable error is created in accordance with the operation mode “3”, the accumulation of the SMART log can be avoided after the management information indicating the pseudo-uncorrectable error is deleted.

Practical Use of Operation Mode 3

When a data recovery or the like is performed in the operation mode “3”, an access to an original error sector becomes an error. However, the SMART log is not newly accumulated even if the reading process is performed on the sector many times. In other words, the HDD can be used again without newly accumulating the SMART log according to the data recovery work.

Operation Mode 4

After a pseudo-uncorrectable error is created in a sector in accordance with the operation mode “2” or “3”, the operation mode “4” is used when wanting to read the sector or temporarily turning off the function (wanting to remove the pseudo-uncorrectable error). For example, after a switching command for switching to the operation mode “4” is issued by the host 100, the formatter unit 231 performs the reading process in accordance with the operation mode “4”.

Practical Use of Operation Mode 4

Depending on the object of a test, it may be necessary to reinstall OS (Operation System) to restore data. However, by using the operation mode “4”, data in a sector in which a pseudo-uncorrectable error is created can be easily read. Moreover, the sector can be easily recovered by using the read data.

There is also a method for previously backing up data in the sector to be tested. However, the method requires an enormous storage in proportion to the increase of the capacity of device and the number of devices. When a pseudo-uncorrectable error is created, because a pseudo error is only present in a state where the original data are held, it is possible not to back up the data by using the operation mode “4”.

Process Related to Storage Device

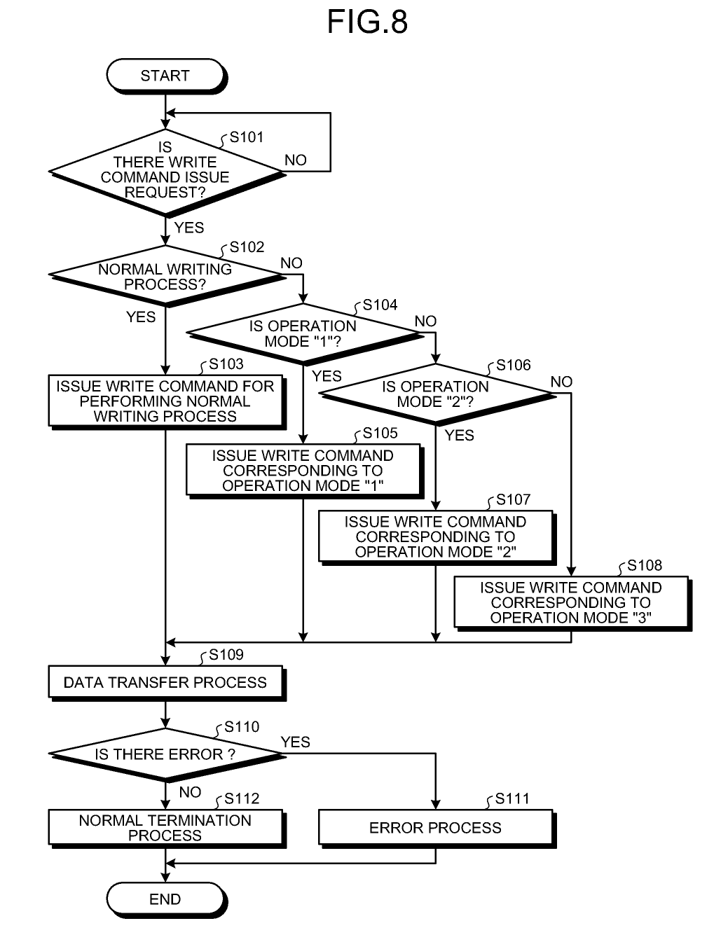

Next, a process related to the storage device according to the first embodiment will be explained. Hereinafter, a read command issuing process performed by the host, a normal writing process performed by the storage device, a writing process for creating an error performed by the storage device, a reading process performed by the storage device, and a process performed by the drive will be sequentially explained with reference to FIG. 8 to FIG. 15.

Write Command Issuing Process by Host

The write command issuing process performed by the host 100 in the first embodiment will be explained with reference to FIG. 8. FIG. 8 is a flowchart for explaining a flow of the write command issuing process performed by the host in the first embodiment.

As illustrated in FIG. 8, when a user requests the issue of a write command (Step S101: YES) and the issue request is a request for a normal writing process (Step S102: YES), the host 100 issues a write command for performing the normal writing process (Step S103). In other words, the host 100 sends an instruction for performing the normal writing process and sector information for identifying a sector to be processed to the formatter unit 231 as the write command.

When the issue request is not a request for the normal writing process (Step S102: NO) and an operation mode is the operation mode “1” (Step S104: YES), the host 100 issues a write command corresponding to the operation mode “1” (Step S105). In other words, the host 100 sends an instruction for performing a writing process creating an uncorrectable error and sector information for identifying a sector to be processed to the formatter unit 231 as the write command.

When the issue request is not a request for the normal writing process (Step S102: NO) and an operation mode is not the operation mode “1” (Step S104: NO) and is the operation mode “2” (Step S106: YES), the host 100 issues a write command corresponding to the operation mode “2” (Step S107). In other words, the host 100 sends an instruction for performing a writing process creating a pseudo-uncorrectable error in accordance with the operation mode “2” and sector information for identifying a sector to be processed to the formatter unit 231 as the write command.

When the issue request is not a request for the normal writing process (Step S102: NO) and an operation mode is not the operation mode “1” (Step S104: NO) and is not the operation mode “2” (Step S106: NO), the host 100 issues a write command corresponding to the operation mode “3” (Step S108). In other words, the host 100 sends an instruction for performing a writing process creating a pseudo-uncorrectable error in accordance with the operation mode “3” and sector information for identifying a sector to be processed to the formatter unit 231 as the write command.

Then, when the command issued, the host 100 performs a data transfer process if required (Step S109). For example, the host 100 performs a data transfer process when sending data to the formatter unit 231 in the issue of the command. Then, the host 100 determines whether there is an error with respect to the issued write command (Step S110). When there is an error (Step S110: YES), for example, when the host 100 accepts information indicating that the writing process has failed from the formatter unit 231, the host 100 performs an error process (Step S111). In other words, for example, the host 100 outputs the information indicating that the writing process has failed to the user. On the other hand, when there is no error (Step S110: NO), the host 100 performs a normal termination process (Step S112). For example, the host 100 outputs the information indicating that the writing process has terminated to the user.

Read Command Issuing Process by Host

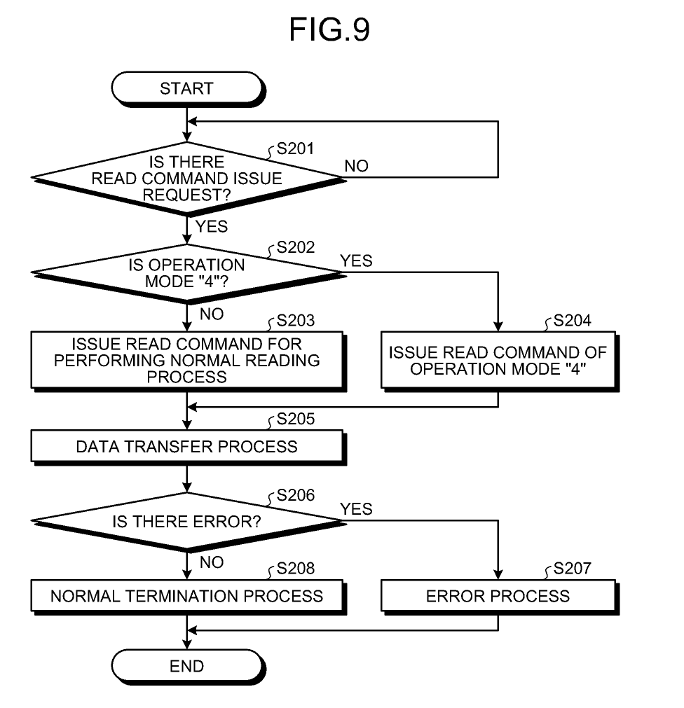

Next, a read command issuing process performed by the host 100 in the first embodiment will be explained with reference to FIG. 9. FIG. 9 is a flowchart for explaining a flow of the read command issuing process performed by the host in the first embodiment.

As illustrated in FIG. 9, when the user requests the issue of a read command (Step S201: YES), the host 100 determines whether the request is the operation mode “4” (Step S202). In this case, when the host 100 determines that the request is not the operation mode “4” (Step S202: NO), the host 100 issues a read command for performing a normal reading process (Step S203). On the other hand, when the host 100 determines that the request is the operation mode “4” (Step S202: YES), the host 100 issues a read command for performing a reading process in accordance with the operation mode “4” (Step S204). In other words, the host 100 sends an instruction for executing the read command in accordance with the operation mode “4” and sector information for identifying a sector to be read to the formatter unit 231 as the read command.

Then, when the command is issued, the host 100 performs a data transfer process if required (Step S205). Then, the host 100 determines whether an error occurs for the issued read command (Step S206). When an error has occurred (Step S206: YES), for example, when the host 100 accepts the information indicating that the reading process has failed from the firm unit 232, the host 100 performs an error process (Step S207). On the other hand, when an error has not occurred (Step S206: NO), the host 100 performs a normal termination process (Step S208). For example, the host 100 outputs the information accepted from the formatter unit 231 to the user.

Normal Writing Process by Storage Device

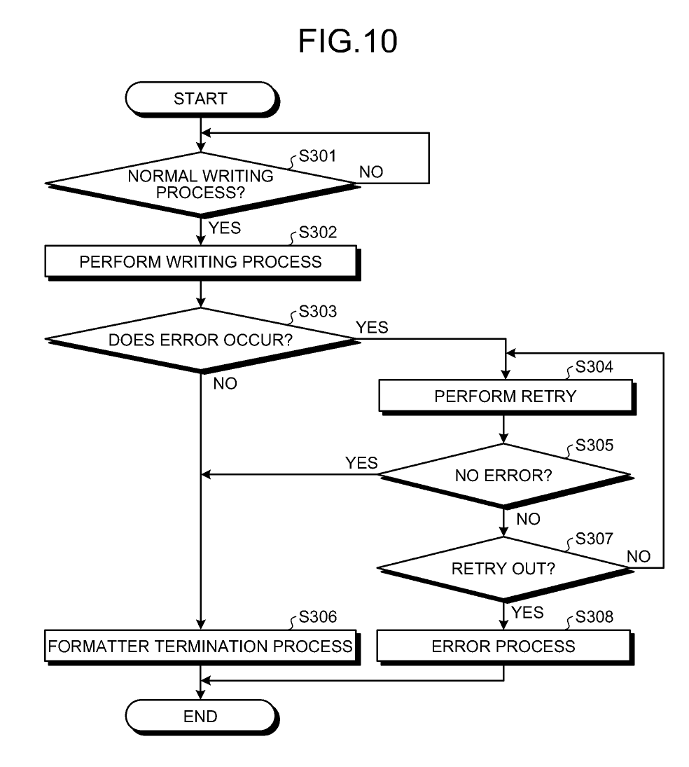

Next, a normal writing process performed by the storage device 200 according to the first embodiment will be explained with reference to FIG. 10. FIG. 10 is a flowchart for explaining a flow of the normal writing process performed by the storage device according to the first embodiment.

As illustrated in FIG. 10, when a command is the write command for performing the normal writing process (Step S301: YES), i.e., when the formatter unit 231 accepts the write command for performing the normal writing process from the host 100, the formatter unit 231 performs the normal writing process (Step S302). In this case, when an error has occurred (Step S303: YES), the formatter unit 231 executes a retry (Step S304). Then, the formatter unit 231 determines whether the error has been fixed (no error?) (Step S305). When the error has been fixed (Step S305: YES), the formatter unit 231 performs a formatter termination process (Step S306). In other words, for example, the formatter unit 231 sends the information indicating that the writing process has terminated to the host 100. In addition, in the Step S303, when the error has not occurred (Step S303: NO), the formatter unit 231 performs the formatter termination process (Step S306).

On the other hand, in Step S305, when the error has not been fixed (Step S305: NO), the formatter unit 231 determines whether the retry has been ended (Step S307). In other words, when the formatter unit 231 determines that the retry has not been ended based on the execution number of retry processes (Step S307: NO), the processes of the Steps S304 to S307 are repeated. On the other hand, when the formatter unit 231 determines that the retry has been ended (Step S307: YES), the formatter unit 231 performs an error process (Step S308) and terminates the process. In other words, for example, the formatter unit 231 sends the information indicating that the writing process has failed to the host 100.

Writing Process for Creating Uncorrectable Error by Storage Device

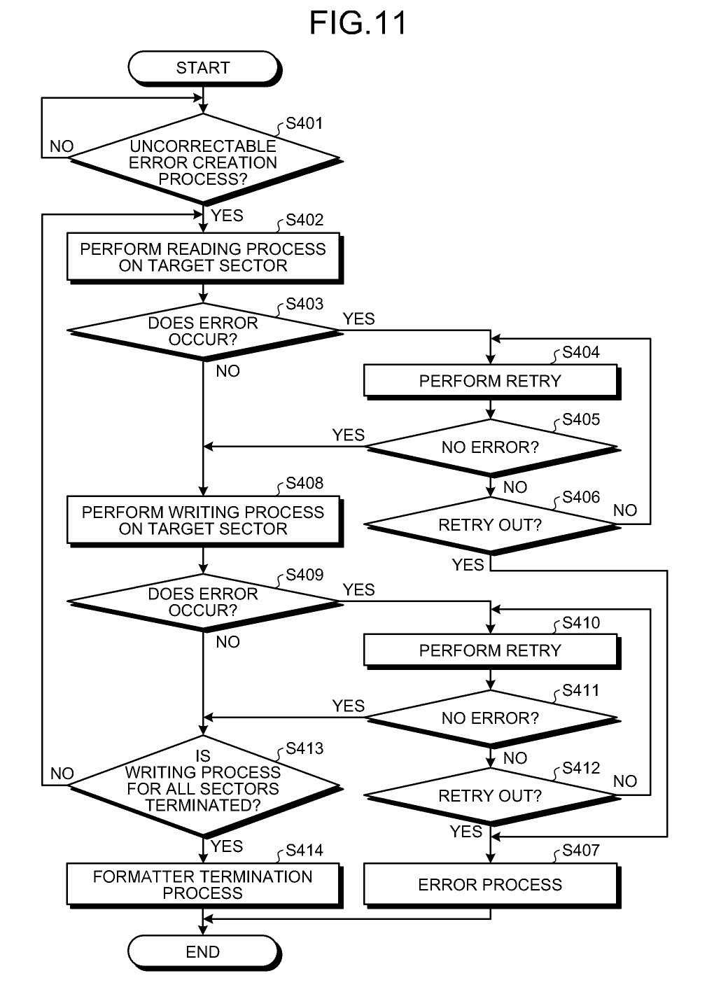

Next, a writing process for creating an uncorrectable error performed by the storage device 200 according to the first embodiment will be explained with reference to FIG. 11. FIG. 11 is a flowchart for explaining a flow of the writing process for creating an uncorrectable error performed by the storage device according to the first embodiment. In FIG. 11, its description is omitted about the processes similar to those of the flowchart explained in FIG. 10.

As illustrated in FIG. 11, when a command is the write command for performing the writing process creating an error (Step S401: YES), i.e., when the formatter unit 231 accepts a write command corresponding to each of the operation modes “1” to “3”, the formatter unit 231 performs a reading process on a sector to be processed (Step S402).

Then, when the reading process is terminated (up to Step S406), the formatter unit 231 performs a writing process on the sector to be processed (Step S408). In other words, the formatter unit 231 performs the writing process by using one of the operation modes “1” to “3” specified by the write command accepted from the host 100.

After that, the formatter unit 231 determines whether the writing process has been terminated for all the sectors specified by the write command (Step S413). In this case, when the formatter unit 231 determines that the writing process has not been terminated for all the sectors (Step S413: NO), the formatter unit 231 repeats the processes of the Steps S402 to S413. On the other hand, when the formatter unit 231 determines that the writing process has been terminated for all the sectors (Step S413: YES), the formatter unit 231 performs a formatter termination process (Step S414) and terminates the process. For example, the formatter unit 231 sends the information indicating that the writing process has been terminated to the host 100.

In addition, Steps S403 to S407 in FIG. 11 correspond to Steps S303 to S305 and S307 in FIG. 10, respectively. Steps S409 to S412 in FIG. 11 correspond to Steps S303 to S305 and S307 in FIG. 10, respectively.

Reading Process by Storage Device

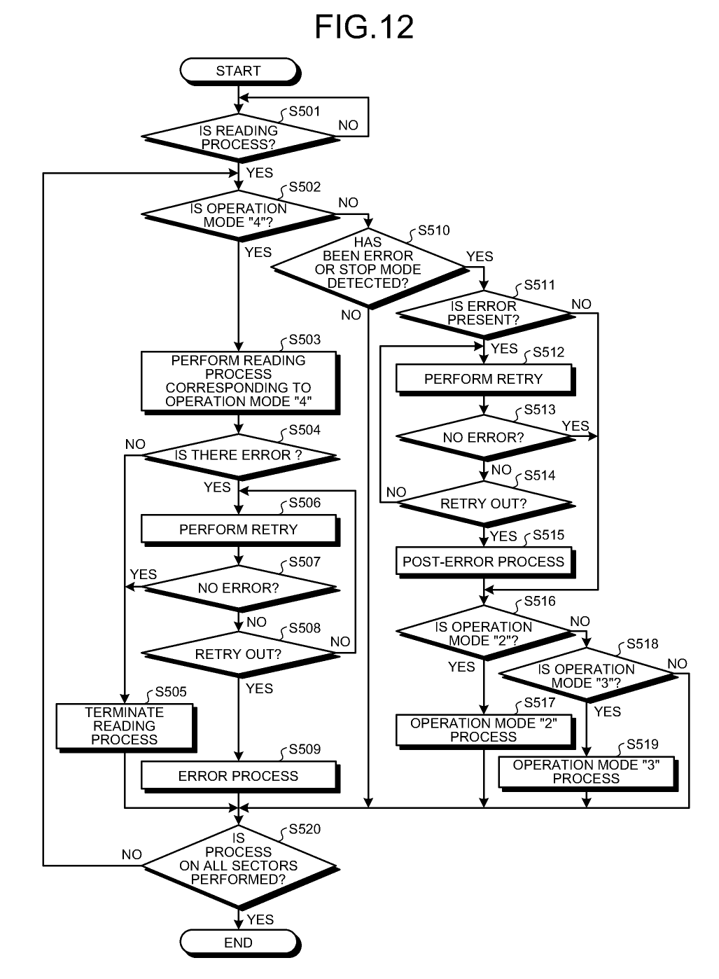

Next, a reading process performed by the storage device 200 according to the first embodiment will be explained with reference to FIG. 12. FIG. 12 is a flowchart for explaining a flow of the reading process performed by the storage device according to the first embodiment.

As illustrated in FIG. 12, when the reading process is performed (Step S501: YES), i.e., when the formatter unit 231 accepts a read command from the host 100, the formatter unit 231 determines whether an operation mode is the operation mode “4” (Step S502). At this time, when an operation mode is the operation mode “4” (Step S502: YES), the formatter unit 231 performs a reading process corresponding to the operation mode “4” (Step S503). In other words, even if management information indicating a pseudo-uncorrectable error is stored in a sector, the formatter unit 231 and the firm unit 232 perform the reading process without performing a process related to the uncorrectable error on the sector.

In this case, the firm unit 232 determines whether there is an error (Step S504). In other words, the firm unit 232 determines whether the firm unit 232 has received the information indicating that the error has been read by the formatter unit 231. When there is no error (Step S504: NO), the firm unit 232 terminates the reading process for the read sector (Step S505). In other words, the firm unit 232 sends information indicating that the process has been terminated to the formatter unit 231, and the formatter unit 231 sends the information indicating that the reading process has been terminated to the host 100.

On the other hand, when there is an error (Step S504: YES), the firm unit 232 executes a retry (Step S506). Then, the firm unit 232 determines whether the error has been fixed (no error?) (Step S507). When the error has been fixed (Step S507: YES), the firm unit 232 terminates the reading process (Step S505).

On the other hand, when the error has not been fixed (Step S507: NO), the firm unit 232 determines whether the retry has been ended (Step S508). In other words, when the firm unit 232 determines that the retry has not been ended based on the execution number of retry processes (Step S508: NO), the firm unit 232 repeats the processes of Steps S506 to S508. When the firm unit 232 determines that the retry has been ended (Step S508: YES), the firm unit 232 performs an error process (Step S509) and terminates the process. In other words, for example, the firm unit 232 sends the information indicating that the reading process has failed to the host 100.

When an operation mode is not the operation mode “4” (Step S502: NO), the firm unit 232 determines whether an error mode or a stop factor is detected by the formatter unit 231 (Step S510). In other words, the firm unit 232 determines whether information indicating that an uncorrectable error has been detected is received from the formatter unit 231 and management information that a bit related to the type of error is “1” indicating a pseudo-uncorrectable error is received from the formatter unit 231.

At this time, when the firm unit 232 determines that the stop factor has been detected (Step S510: YES) and receives the information indicating that an uncorrectable error has been detected (Step S511: YES), the firm unit 232 performs a retry process (Steps S512 to S515).

Then, when the firm unit 232 does not receive the information indicating that the uncorrectable error has been detected (Step S511: NO) and the retry process has been terminated (up to Step S515), the firm unit 232 determines whether an operation mode is the operation mode “2” (Step S516). In other words, the firm unit 232 determines whether “11” is received as management information. At this time, when the firm unit 232 determines that an operation is the operation mode “2” (Step S516: YES), the firm unit 232 performs the reading process related to the operation mode “2” on the sector (Step S517). In other words, the firm unit 232 sends the information indicating that the uncorrectable error is present in the sector to the host 100 and also registers the SMART log related to the uncorrectable error in the storage unit 220.

On the other hand, when the firm unit 232 determines that an operation is not the operation mode “2” (Step S516: NO), the firm unit 232 determines whether an operation mode is the operation mode “3” (Step S518). In other words, the firm unit 232 determines whether “10” is received as management information. At this time, when the firm unit 232 determines that an operation mode is the operation mode “3” (Step S518: YES), the firm unit 232 performs the reading process related to the operation mode “3” on the sector (Step S519). In other words, the firm unit 232 sends the information indicating that the uncorrectable error is present in the sector to the host 100 and does not register the SMART log related to the uncorrectable error in the storage unit 220. On the other hand, when the firm unit 232 does not determine that an operation is the operation mode “3” (Step S518: NO), the firm unit 232 terminates the reading process for the sector.

After that, the formatter unit 231 determines whether the process is performed on all the sectors (Step S520). When the formatter unit 231 determines that the process has been performed on all the sectors (Step S520: YES), the formatter unit 231 terminates the process. When the formatter unit 231 determines that the process has not been performed on all the sectors (Step S520: NO), the formatter unit 231 repeats the processes of the Steps S502 to S519.

In addition, Steps S512 to S515 in FIG. 12 correspond to Steps S505 and S507 to S509 in FIG. 12.

Process by Drive

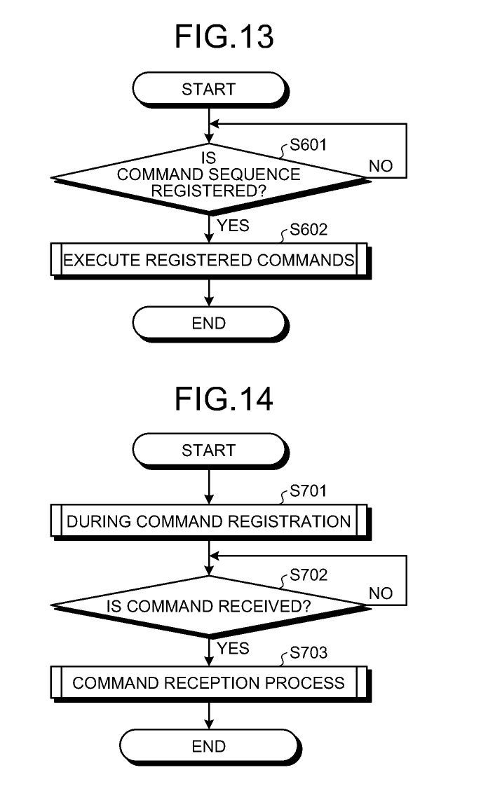

Next, processes performed by the drive 210 in the first embodiment will be explained with reference to FIG. 13 to FIG. 15. The processes explained below are a command reception process in an idle state, a command interrupt process, and a command execution process.

Command Reception Process in Idle State

A command reception process in an idle state performed by the drive 210 in the first embodiment will be explained with reference to FIG. 13. FIG. 13 is a flowchart for explaining a flow of the command reception process in an idle state performed by the drive in the first embodiment.

As illustrated in FIG. 13, when a command sequence input from the control unit 230 is registered in the drive 210 in an idle state (Step S601: YES), the drive 210 executes the registered commands (Step S602). In other words, the drive 210 sequentially executes the commands registered in the command sequence.

Command Interrupt Process

Next, a command interrupt process performed by the drive 210 in the first embodiment will be explained with reference to FIG. 14. FIG. 14 is a flowchart for explaining a flow of the command interrupt process performed by the drive in the first embodiment.

As illustrated in FIG. 14, during a command registration (Step S701), i.e., when commands are received and are registered in a command sequence, if the drive 210 further receives another command (Step S702: YES), the drive 210 registers the command (Step S703).

Command Execution Process

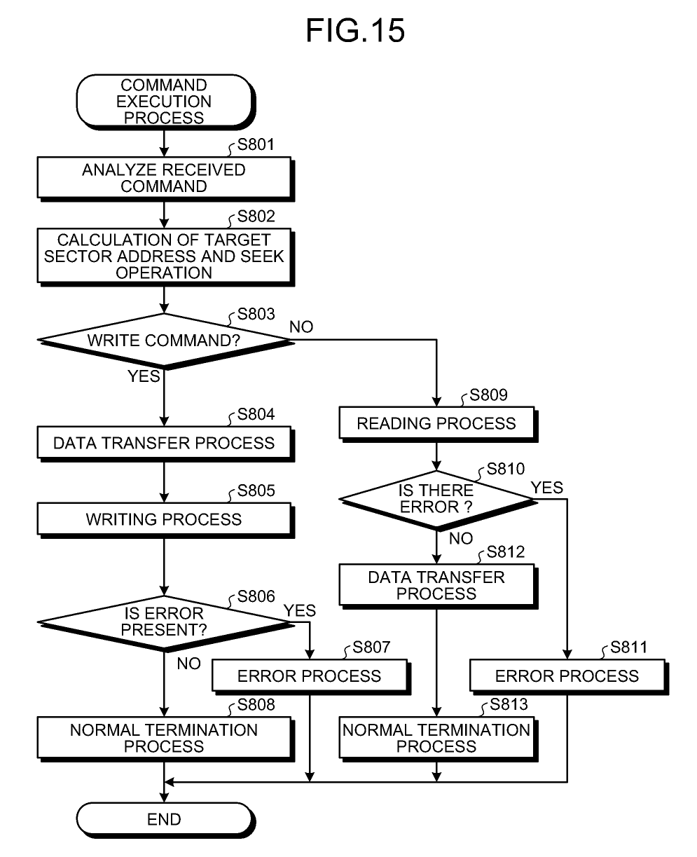

Next, a command execution process performed by the drive 210 in the first embodiment will be explained with reference to FIG. 15. FIG. 15 is a flowchart for explaining a flow of the command execution process performed by the drive in the first embodiment.

As illustrated in FIG. 15, when executing a command, the drive 210 analyzes the commands registered in the command sequence (Step S801), calculates an address indicating a sector to be processed, and seeks an area specified by the address in the drive 210 (Step S802).

At this time, when the command to be executed is a write command (Step S803: YES), the drive 210 performs a data transfer process for transferring information that is stored in the drive 210 from the control unit 230 if required (Step S804). After that, the drive 210 performs the writing process (Step S805). In other words, the drive 210 writes the information on a medium included in the drive 210. Then, when an error has occurred (Step S806: YES), the drive 210 performs an error process (Step S807). For example, the drive 210 sends the information indicating that the writing process has failed to the control unit 230. On the other hand, when the error has not occurred (Step S806: NO), the drive 210 performs a normal termination process (Step S808). For example, the drive 210 sends the information indicating that the writing process has been normally terminated to the control unit 230.

On the other hand, when the command to be executed is not a write command (Step S803: NO) but a read command, the drive 210 performs the reading process (Step S809). Then, when an error has occurred (Step S810: YES), the drive 210 performs an error process (Step S811). For example, the drive 210 sends the information indicating that the reading process has failed to the control unit 230. On the other hand, when the error has not occurred (Step S810: NO), the drive 210 performs a process for transferring the read information to the control unit 230 if required (Step S812) and performs a normal termination process (Step S813). For example, the drive 210 sends the information indicating that the reading process has been normally terminated to the control unit 230.

Effect of First Embodiment

As described above, according to the first embodiment, the storage device 200 stores identification information for identifying a pseudo-uncorrectable error sector in the pseudo-uncorrectable error sector and performs data processing on the sector by using the identification information stored in the sector. As a result, the identification information can be appropriately stored.

For example, unlike with a technique for storing identification information in a memory that stores therein the identification information, identification information can be stored even when identification information for all sectors is stored.

Moreover, for example, compared to a technique for managing identification information as a table in a memory or the like that stores therein the identification information, data processing using identification information can be quickly performed. In other words, in the management technique using a table, it is necessary to perform a process referring to a table whenever data processing is performed using the identification information. Moreover, in the management technique using a table, the more the number of identification information managed by the table is increased, the more a processing load is increased when referring to the table.

Compared to the management technique using a table, the storage device of the first embodiment can remove a process referring to a table and thus can quickly perform a process.

Moreover, according to the first embodiment, because the storage device 200 stores log process information in a pseudo-uncorrectable error sector and performs data processing by using the log process information and the identification information, the storage device 200 can appropriately store therein the log process information similarly to the storage of the identification information.

Moreover, according to the first embodiment, because the storage device 200 performs data processing on a sector without the use of management information when accepting an instruction indicating that data processing is performed without the use of the management information, the storage device 200 can perform data processing related to the sector without regard to the management information even if the sector is a sector in which the identification information indicating a pseudo-uncorrectable error sector is stored.

For example, in the case of the pseudo-uncorrectable error sector, data within the pseudo-uncorrectable error sector can be read by performing the reading process by using the operation mode “4” when a process for reading out the data within the sector is not performed.

### [b] Second Embodiment

Explained above is an embodiment of the present invention. The present invention may be performed in accordance with another embodiment in addition to the embodiment as described above. Therefore, it will be explained about a second embodiment as described below.

Management Information Storage Position

For example, according to the first embodiment, it has been explained about when management information is written into a dedicated area “information” that is located between “DATA” and “ECC”. However, the present invention is not limited to this and thus may write management information into an arbitrary area. For example, when a fractional portion caused by encoding or decoding is present in “data” or “ECC” area, management information may be written into the area. As a result, identification information can be stored in a sector without deteriorating the efficiency of sector format. In other words, identification information can be stored in a sector by using an area that is not originally used because a fractional area caused by encoding or decoding in the DATA area or the ECC area present in an area of the sector is used.

Management Information

According to the first embodiment, although it has been explained about when identification information and log process information are together used as management information, the present invention is not limited to this and may not use a bit indicating the presence or absence of the registration of SMART log.

Moreover, according to the first embodiment, although it has been explained about when a bit related to the type of error and a bit indicating the presence or absence of the registration of SMART log are used as management information, the present invention is not limited to this.

For example, the number of writings obtained by performing writing processes on each sector may be recorded for each sector. In other words, for example, a storage area in a medium included in the drive 210 is divided into zones or some thousand LBA units. The storage device 200 manages the number of writings by the unit by using the number of writings for each sector. For example, the storage device 200 includes a memory and manages the number of writings by the unit on the memory.

In this case, the storage device 200 monitors whether the number of writings reaches a predetermined threshold value. When the number of writings reaches the predetermined threshold value, the storage device 200 performs a re-writing process (a writing operation after reading data from a target sector) for each management unit. Moreover, the storage device 200 collects the number of writings for each management unit in response to SMART-function Self Test (or a command output from the host) and also performs a re-writing process for each management unit when the number of writings reaches a threshold value at which a side erasing effect seems to occur. A side erasing effect means that information is recorded in an adjacent sector as well as a sector to be recorded. Moreover, when an error occurs and then the error is fixed by the retry of error, the storage device 200 collects the number of writings and performs a rewriting process when the error can be fixed by the retry. The storage device 200 may perform a rewriting process and a monitoring process as a background. As a result, the storage device 200 can perform a measure such as an appropriate rewriting process before the attribute of a medium deteriorates.

Moreover, temperature information may be together used as management information. In other words, depending on a temperature condition for performing a writing process, an uncorrectable error can be easy to occur if a temperature condition at a reading process after the writing process is different from the temperature condition at the writing process. In this case, the storage device 200 writes temperature information in a sector and uses the temperature information during the reading process. Therefore, the occurrence of uncorrectable error can be suppressed. Moreover, for example, the storage device 200 can read temperature information when an error occurs and then the error is fixed by the retry and can perform a reading process or the like in accordance with the temperature condition at the time of the next reading process or a retry process. As a result, the storage device 200 can suppress performance deterioration according to the occurrence of error to the minimum.

In addition, the storage device 200 may update only management information of the number of writings during the writing process and may also perform a process using management information such as temperature information or the number of writings only when an error is detected during the reading process. As a result, the storage device 200 can be realized without having an influence on the performance of the reading process when an error does not occur.

System Configuration

In the meantime, among the processes described in the present embodiments, the whole or a part of processes that have been automatically performed can be manually performed. Alternatively, the whole or a part of processes that have been manually performed can be automatically performed in a well-known method. Also, processing procedures, control procedures, concrete titles, and information including various types of data and parameters, which are described in the document and the drawings, can be arbitrarily changed except that they are specially mentioned (for example, FIGS. 1 to 9).

Moreover, each component of each device illustrated in the drawings is a functional concept. Therefore, these components are not necessarily constituted physically as illustrated in the drawings. In other words, the specific configuration of dispersion/integration of each device is not limited to the illustrated configuration. Therefore, all or a part of each device can dispersed or integrated functionally or physically in an optional unit in accordance with various types of loads or operating conditions.

Computer

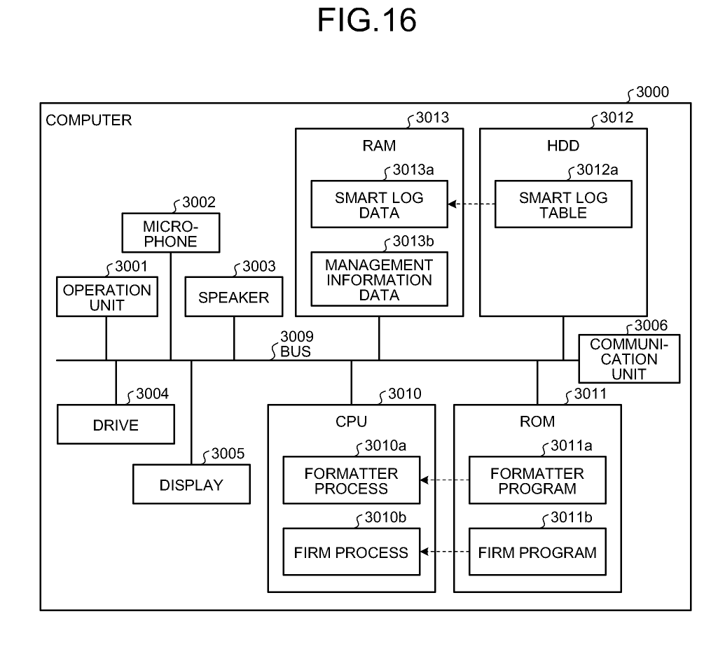

The processes described in the present embodiments can be realized by executing a program prepared beforehand with a computer such as a personal computer or a workstation. Hereinafter, an example of a computer for executing a program having a function similar to that of the embodiment will be explained with reference to FIG. 16. FIG. 16 is a diagram for explaining a computer 3000 having the same function as that of the storage device according to the first embodiment.

As illustrated in FIG. 16, the computer 3000 includes an operation unit 3001, a microphone 3002, a speaker 3003, a drive 3004, a display 3005, a communication unit 3006, a CPU (Central Processing Unit) 3010, a ROM 3011, an HDD 3012, and a RAM (Random Access Memory) 3013, which are connected through a bus 3009. In addition, the drive 3004 corresponds to the drive 210 illustrated in FIG. 2.

The ROM 3011 previously stores therein a control program that shows a function similar to that of the formatter unit 231 and the firm unit 232 according to the first embodiment, i.e., a formatter program 3011a and a firm program 3011b as illustrated in FIG. 16. In addition, these programs 3011a and 3011b may be appropriately integrated or separated similarly to the components of the storage device 200 illustrated in FIG. 2.

The CPU 3010 reads and executes the programs 3011a and 3011b from the ROM 3011, and thus the programs 3011a and 3011b function as a formatter process 3010a and a firm process 3010b as illustrated in FIG. 16. In addition, the processes 3010a and 3010b correspond to the formatter unit 231 and the firm unit 232 illustrated in FIG. 2, respectively.

The HDD 3012 includes therein a SMART log table 3012a. The CPU 3010 reads the SMART log table 3012a and stores the table in the RAM 3013. Then, the CPU 3010 executes a program by using a SMART log data 3013a and a management information data 3013b stored in the RAM 3013.

Others

The storage device described in the present embodiment can be realized by executing a program prepared beforehand with a computer such as a personal computer or a workstation. The program can be distributed via a network such as Internet. Moreover, the program can be recorded in a recording medium, which can be read by the computer, such as a hard disk, a flexible disk (FD), a CD-ROM, an MO, or a DVD and can be executed by being read from the recording medium by the computer.

As described above, according to an embodiment, identification information can be stored appropriately.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A storage device comprising:
a storage control unit that stores identification information for identifying a pseudo-uncorrectable error sector in the pseudo-uncorrectable error sector, the pseudo-uncorrectable error sector being treated in a pseudo manner as a sector including an uncorrectable error; and
a data processing control unit that performs data processing on the sector by using the identification information stored in the sector by the storage control unit.

2. The storage device according to claim 1, further comprising a log-process-information storage control unit that stores log process information in the pseudo-uncorrectable error sector in an error process related to the uncorrectable error that is treated to be included in a pseudo manner, the log process information indicating whether an error log is registered in the pseudo-uncorrectable error sector, wherein
the data processing control unit performs the data processing by using the log process information stored by the log-process-information storage control unit and the identification information.

3. The storage device according to claim 1, wherein
the sector includes a data area where data is stored and an ECC area where information used for correcting an error included in the data area is stored, and
the storage control unit stores the identification information in a fractional area in the data area or a fractional area in the ECC area.

4. The storage device according to claim 1, wherein the data processing control unit, when accepting an instruction indicating that the data processing is performed without the use of the identification information, performs the data processing on the sector without the use of the identification information stored by the storage control unit.

5. A control device comprising a data processing control unit that performs data processing on a sector by using identification information for identifying a pseudo-uncorrectable error sector, the pseudo-uncorrectable error sector being treated in a pseudo manner as the sector including an uncorrectable error, the identification information being stored in the pseudo-uncorrectable error sector.

6. A computer readable storage medium containing instructions that, when executed by a computer, cause the computer to perform data processing on a sector by using identification information for identifying a pseudo-uncorrectable error sector, the pseudo-uncorrectable error sector being treated in a pseudo manner as the sector including an uncorrectable error, the identification information being stored in the pseudo-uncorrectable error sector.
